(19) United States
(12) Patent Application Publication
(10) Pub. No.: US 2025/0210575 A1
(43) Pub. Date: Jun. 26, 2025

(54) BONDING STRUCTURE AND PRE-BONDING STRUCTURE

(71) Applicant: Advanced Semiconductor Engineering, Inc., Kaohsiung (TW)

(72) Inventors: Yun-Ching HUNG, Kaohsiung (TW); Chun-Wei CHIANG, Kaohsiung (TW); Yung-Sheng LIN, Kaohsiung (TW)

(73) Assignee: Advanced Semiconductor Engineering, Inc., Kaohsiung (TW)

(21) Appl. No.: 18/391,585

(22) Filed: Dec. 20, 2023

(51) Int. Cl. H01L 23/00

(52) U.S. Cl. CPC H01L 24/32; H01L 24/29; H01L 2224/29083; H01L 2224/32145

(57) ABSTRACT

A bonding structure and a pre-bonding structure are provided. The bonding structure includes a lower substrate; a low melting point conductive layer disposed over the lower substrate; a high melting point conductive layer including a lower portion and an upper portion, wherein the low melting point conductive layer is between the upper portion and the lower portion of the high melting point conductive layer; a dielectric layer encapsulating the low melting point conductive layer and the high melting point conductive layer; and an upper substrate disposed on the upper portion of the high melting point conductive layer, wherein an interface between the upper substrate and the high melting point conductive layer is substantially co-level with an interface between the dielectric layer and the upper substrate.

### BACKGROUND

### 1. Technical Field

The present disclosure relates generally to a bonding structure and a pre-bonding structure.

### 2. Description of the Related Art

Currently, copper pads are hybrid-bonded to each other through a conductive adhesion layer and a dielectric layer covering the conductive adhesion layer. An opening or a through hole may be formed in the dielectric layer, and the conductive adhesion layer may be formed in the opening or the through hole of the dielectric layer. The conductive adhesion layer may be formed by electroless displacement deposition and thus have a relatively small thickness, and a thinning operation is required to be performed on the dielectric layer to expose the conductive adhesion layer for bonding. However, in order to expose the relatively thin conductive adhesion layer, the dielectric layer may become too thin after the thinning operation, which is disadvantageous to the subsequent hybrid bonding operation.

### SUMMARY

In one or more arrangements, a bonding structure includes a lower substrate; a low melting point conductive layer disposed over the lower substrate; a high melting point conductive layer including a lower portion and an upper portion, wherein the low melting point conductive layer is between the upper portion and the lower portion of the high melting point conductive layer; a dielectric layer encapsulating the low melting point conductive layer and the high melting point conductive layer; and an upper substrate disposed on the upper portion of the high melting point conductive layer, wherein an interface between the upper substrate and the high melting point conductive layer is substantially co-level with an interface between the dielectric layer and the upper substrate.

In one or more arrangements, a pre-bonding structure includes a substrate; a bonding layer disposed over the substrate; and a pre-bonding layer encapsulating the bonding layer and exposing a top surface of the bonding layer, wherein a thickness of the pre-bonding layer is configured to prevent the substrate from being exposed by the pre-bonding layer during a thinning operation for the pre-bonding layer.

In one or more arrangements, a pre-bonding structure includes a substrate including a pad; a bonding layer over the substrate and spaced apart from the pad, wherein a melting point of the bonding layer is lower than a melting point of the pad; and a pre-bonding layer encapsulating the bonding layer and exposing the bonding layer, wherein a top end of a lateral surface of the bonding layer is substantially aligned with a top surface of the pre-bonding layer.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a bonding structure in accordance with some arrangements of the present disclosure.

FIG. 1B is a cross-section of a bonding structure in accordance with some arrangements of the present disclosure.

FIG. 1C is a cross-section of a pre-bonding structure in accordance with some arrangements of the present disclosure.

FIG. 1D is a cross-section of a pre-bonding structure in accordance with some arrangements of the present disclosure.

FIG. 2A is a cross-section of a bonding structure in accordance with some arrangements of the present disclosure.

FIG. 2B is a cross-section of a bonding structure in accordance with some arrangements of the present disclosure.

FIG. 2C is a cross-section of a bonding structure in accordance with some arrangements of the present disclosure.

FIG. 2D is a cross-section of a portion of a bonding structure in accordance with some arrangements of the present disclosure.

FIG. 2E is a cross-section of a portion of a bonding structure in accordance with some arrangements of the present disclosure.

FIG. 2F is a cross-section of a portion of a bonding structure in accordance with some arrangements of the present disclosure.

FIG. 2G is a cross-section of a bonding structure in accordance with some arrangements of the present disclosure.

FIG. 2H is a cross-section of a pre-bonding structure in accordance with some arrangements of the present disclosure.

FIG. 2I is a scanning electron microscope (SEM) image of a cross-section of a bonding structure in accordance with some arrangements of the present disclosure.

FIG. 3A is a top view of a bonding structure in accordance with some arrangements of the present disclosure.

FIG. 3B is a cross-section of a bonding structure in accordance with some arrangements of the present disclosure.

FIG. 4A, FIG. 4B, FIG. 4C, FIG. 4D, FIG. 4E, and FIG. 4F illustrate various stages of an exemplary method for manufacturing a bonding structure in accordance with some embodiments of the present disclosure.

FIG. 5A illustrates one or more stages of an exemplary method for manufacturing a bonding structure in accordance with some embodiments of the present disclosure.

FIG. 5B illustrates one or more stages of an exemplary method for manufacturing a bonding structure in accordance with some embodiments of the present disclosure.

FIG. 6A, FIG. 6B, and FIG. 6C illustrate various stages of an exemplary method for manufacturing a bonding structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

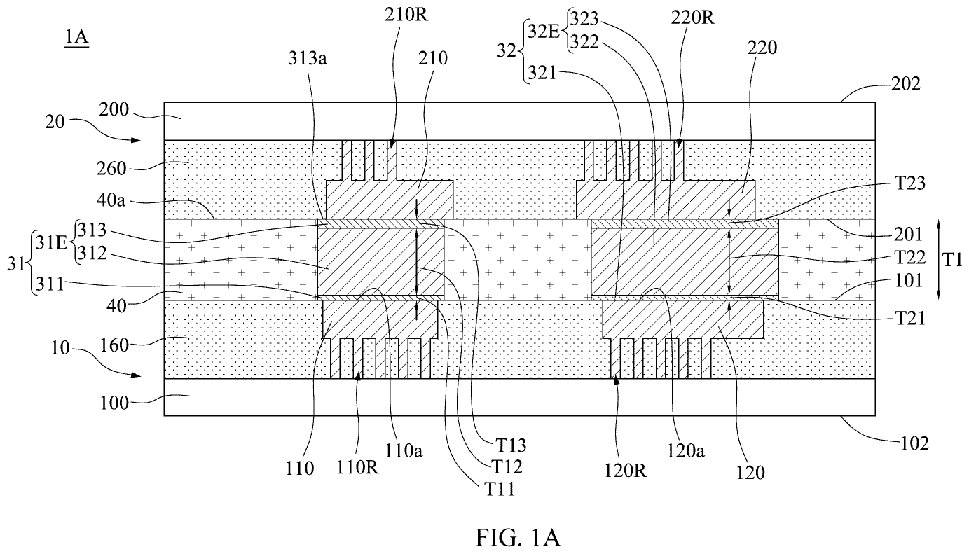

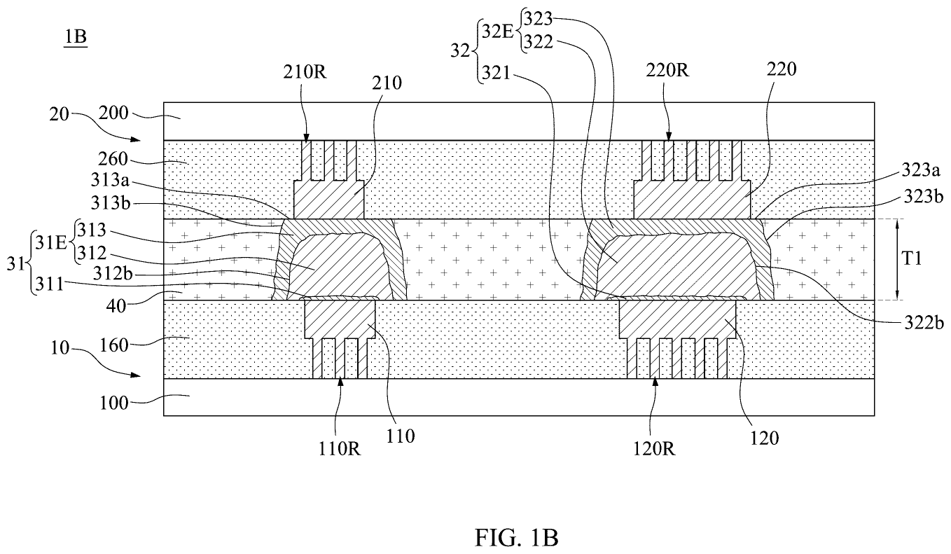

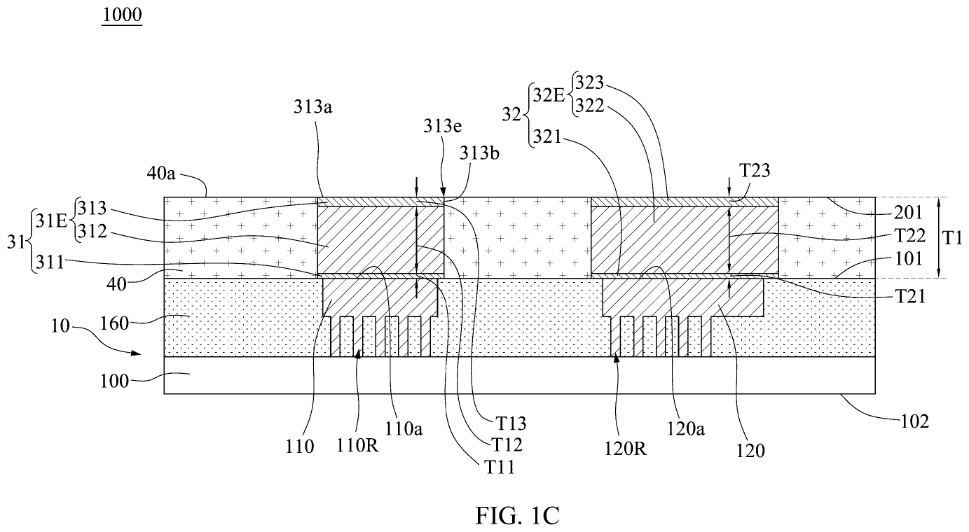

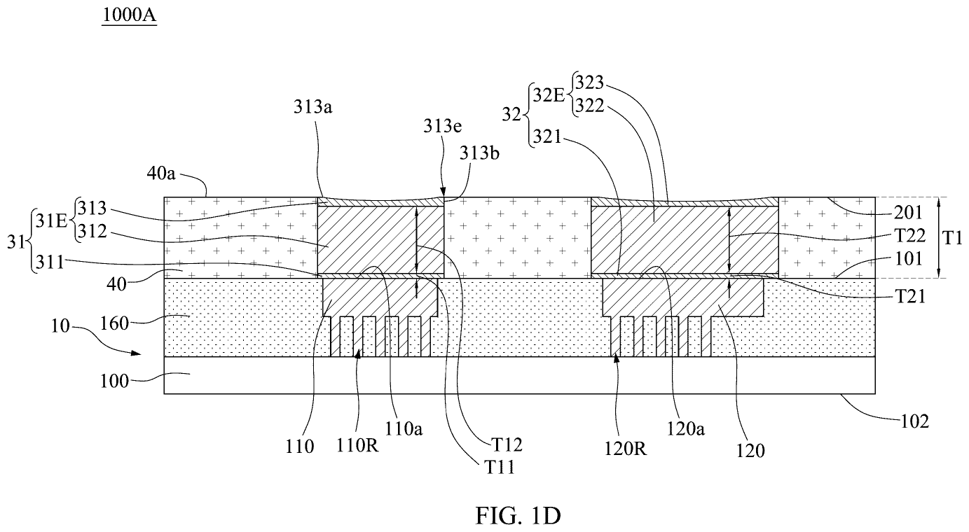

FIG. 1A is a cross-section of a bonding structure 1A in accordance with some arrangements of the present disclosure. The bonding structure 1A may include substrates 10 and 20, bonding structures 31 and 32, and a protective layer 40

The substrates 10 and 20 may independently include, for example, a printed circuit board, such as a paper-based copper foil laminate, a composite copper foil laminate, or a polymer-impregnated glass-fiber-based copper foil laminate. The substrates 10 and 20 may independently include an interconnection structure, which may include a plurality of conductive traces and/or conductive vias. The interconnection structure may include a redistribution layer (RDL) and/or a grounding element. In some arrangements, the substrates 10 and 20 may independently include an organic substrate or a leadframe. In some arrangements, the substrates 10 and 20 may independently include a ceramic material or a metal plate. In some arrangements, the substrates 10 and 20 may independently include a two-layer substrate which includes a core layer and a conductive material and/or structure disposed on an upper surface and a bottom surface of the substrate. The substrates 10 and 20 may independently include a semiconductor wafer or an electronic component. The electronic component may be a chip or a die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the substrates 10 and 20 may independently include one or more conductive elements, surfaces, contacts, or pads.

In some arrangements, the substrate 10 has a surface 101 and a surface 102 opposite to the surface 101. In some arrangements, the substrate 10 includes a base layer 100, terminals 110 and 120 (also referred to as “conductive pads” or “conductive layers”), interconnection elements 110R and 120R, and a dielectric layer 160. The terminals 110 and 120 may be or include conductive terminals. The base layer 100 may be or include a semiconductor substrate or other suitable materials or elements included in the substrate 10 as described above. In some arrangements, the terminals 110 and 120 and the interconnection elements 110R and 120R are in the dielectric layer 160. The dielectric layer 160 may be or include a semiconductor oxide (e.g., SiOx), an organic material (e.g., polyimide), or any suitable dielectric material. In some arrangements, the terminals 110 and 120 are electrically connected to the base layer 100 through the interconnection elements 110R and 120R. The interconnection elements 110R and 120R may be or include conductive vias, conductive pillars, or other suitable electrical connection elements. In some arrangements, the terminals 110 and 120 (or the conductive pads) are exposed by the surface 101. In some arrangements, the terminals 110 and 120 are exposed by the dielectric layer 160. In some arrangements, the terminals 110 and 120 have different widths. The substrate 10 may be referred to as a lower substrate.

In some arrangements, the substrate 20 has a surface 201 and a surface 202 opposite to the surface 201. In some arrangements, the substrate 20 includes a base layer 200, terminals 210 and 220 (also referred to as “conductive pads” or “conductive layers”), interconnection elements 210R and 220R, and a dielectric layer 260. The base layer 200 may be or include a semiconductor substrate or other suitable materials or elements included in the substrate 20 as described above. In some arrangements, the terminals 210 and 220 and the interconnection elements 210R and 220R are in the dielectric layer 260. The dielectric layer 260 may be or include a semiconductor oxide (e.g., SiOx), an organic material (e.g., polyimide), or any suitable dielectric material. In some arrangements, the terminals 210 and 220 are electrically connected to the base layer 200 through the interconnection elements 210R and 220R. The interconnection elements 210R and 220R may be or include conductive vias, conductive pillars, or other suitable electrical connection elements. In some arrangements, the terminals 210 and 220 (or the conductive pads) are exposed by the surface 201. In some arrangements, the terminals 210 and 220 are exposed by the dielectric layer 260. In some arrangements, the terminals 210 and 220 have different widths. The substrate 20 may be referred to as an upper substrate.

The bonding structures 31 and 32 may be between the substrate 10 and the substrate 20. In some arrangements, the bonding structures 31 and 32 electrically connect the substrate 10 and the substrate 20. In some arrangements, the bonding structure 31 includes an electrical connection structure 31E and a catalytic layer 311. In some arrangements, the bonding structure 32 includes an electrical connection structure 32E and a catalytic layer 321.

In some arrangements, the electrical connection structure 31E is over the terminal 110. In some arrangements, the electrical connection structure 31E includes an interlayer 312 and a bonding layer 313. The interlayer 312 may be referred to as an interconnection element, and the bonding layer 313 may be referred to as a bonding pad. In some arrangements, the interlayer 312 is configured to raise an elevation of the bonding layer 313 so as to increase a thickness T1 of the protective layer 40. Therefore, when a thinning operation (e.g., the CMP operation) is performed on the protective layer 40 to expose the bonding layer 313, with the thickness T1 of the protective layer 40 being relatively large, the processing window of the thinning operation (e.g., the CMP operation) for the protective layer 40 is enlarged, and thus the polishing rate or the grinding rate of the thinning operation can be relatively high without accidentally damaging the substrate 10. Therefore, the time of the thinning operation for the protective layer 40 can be reduced.

In some arrangements, the catalytic layer 311 is between the terminal 110 and the electrical connection structure 31E. In some arrangements, the catalytic layer 311 is between the terminal 110 and the interlayer 312. In some arrangements, the catalytic layer 311 is formed or directly contacts a surface 110a of the terminal 110. In some arrangements, a catalytic activity of the catalytic layer 311 is greater than a catalytic activity of the terminal 110. In some arrangements, the catalytic layer 311 has a catalytic activity for formation of the interlayer 312 greater than that of the terminal 110. In some arrangements, a rate of formation of the interlayer 312 on the catalytic layer 311 is greater than a rate of formation of the interlayer 312 on the terminal 110. In some arrangements, a ratio of the rate of formation of the interlayer 312 on the catalytic layer 311 to the rate of formation of the interlayer 312 on the terminal 110 is greater than 1, for example, from about 10 to about 1000, or from about 50 to about 800. In some arrangements, there is no seed layer between the catalytic layer 311 and the interlayer 312. The catalytic layer 311 may be formed by electroless plating. In some arrangements, the catalytic layer 311 is formed by electroless displacement deposition. In some arrangements, the catalytic layer 311 may be or include an electroless plating layer. In some arrangements, the catalytic layer 311 may be formed of or include silver (Ag), gold (Au), platinum (Pt), palladium (Pd), or a combination thereof. In some arrangements, the catalytic layer 311 may have a thickness T11 less than about 0.5 μm. When charges may accumulate on the edge of the surface 110a of the terminal 110, the interlayer 312 formed directly on the surface 110a of the terminal 110 may have a relatively large thickness on the edge of the surface 110a and a relatively small thickness on the center of the surface 110a, resulting in a non-uniform thickness of the interlayer 312. In some arrangements, the rate of formation of the interlayer 312 on the catalytic layer 311 is significantly greater than the rate of formation of the interlayer 312 on the terminal 110. The relatively high catalytic activity of the catalytic layer 311 dominates the formation mechanism of the interlayer 312, and the influence of the distribution of charges on the growth rate of the interlayer 312 is minimized or even can be omitted. Therefore, the interlayer 312 can be formed with a relatively large and uniform thickness. In some arrangements, the catalytic layer 311 is formed or deposited prior to or earlier than forming or depositing the interlayer 312. In some arrangements, the catalytic layer 311 is closer to the terminal 110 than the interlayer 312 is. With the above arrangements of the catalytic layer 311 and the interlayer 312, the aforementioned effects (e.g., reducing the time of the thinning operation, increasing the uniformity of the thickness of the interlayer 312, and etc.) can be achieved effectively.

In some arrangements, the interlayer 312 is at least partially between the catalytic layer 311 and the bonding layer 313 (or the bonding pad). In some arrangements, a width of the interlayer 312 is greater than a width of the catalytic layer 311. The interlayer 312 may be formed by electroless plating. In some arrangements, the interlayer 312 may be or include an electroless plating layer. In some arrangements, the interlayer 312 may be formed of or include gold (Au), aluminum (Al), copper (Cu), or an alloy thereof. In some arrangements, the interlayer 312 and the catalytic layer 311 include or are formed of different materials. In some arrangements, the interlayer 312 is referred to as a raised layer or a raised portion configured to increase a height or a thickness of the electrical connection structure 31E. In some arrangements, the interlayer 312 (or the raised layer) is configured to raise an elevation of the bonding layer 313 (or the bonding pad) with respect to the surface 101 of the substrate 10. In some arrangements, the interlayer 312 (or the raised layer) is configured to raise an elevation of the bonding layer 313 (or the bonding pad) to create an enlarged gap between the substrate 10 and the substrate 20 for accommodating the protective layer 40. In some arrangements, the interlayer 312 is configured to raise an elevation of the bonding layer 313 so as to increase the thickness T1 of the protective layer 40. Therefore, with the thickness T1 of the protective layer 40 being relatively large, the processing window of the thinning operation (e.g., the CMP operation) for the protective layer 40 is enlarged, and thus the polishing rate or the grinding rate of the thinning operation can be relatively high without accidentally damaging the substrate 10. Therefore, the time of the thinning operation for the protective layer 40 can be reduced. In some arrangements, the interlayer 312 (or the raised layer) is configured to define a thickness T1 of the protective layer 40 to prevent the dielectric layer 160 from being exposed by the protective layer 40. In some arrangements, the thickness T1 of the protective layer 40 is greater than a thickness T12 of the interlayer 312. In some arrangements, the thickness T12 of the interlayer 312 is equal to or greater than about 1 μm, for example, from about 1 μm to about 2 μm or from about 1 μm to about 1.5 μm. According to some arrangements of the present disclosure, the protective layer 40 serves as a pre-bonding layer that softens when the processing temperature reaches the glass transition temperature (Tg) of the protective layer 40 and bonds the substrates 10 and 20, the protective layer 40 having a relatively large thickness can increase the bonding strength between the substrate 10 and 20, and can further reduce damages to the bonding structure resulted caused by impact or friction of the substrate 20.

In some arrangements, the bonding layer 313 is over the terminal 110. In some arrangements, the bonding layer 313 is between the terminal 110 and the terminal 210. The bonding layer 313 may be formed by electroless plating. In some arrangements, the bonding layer 313 may be or include an electroless plating layer. In some arrangements, the bonding layer 313 may be formed of or include a material having a melting point lower than that of the terminal 110. The bonding layer 313 may be referred to as a low melting point conductive layer. In some arrangements, the bonding layer 313 may be formed of or include Ag or an alloy thereof. In some arrangements, the thickness T11 of the catalytic layer 311 is less than a thickness T13 of the bonding layer 313. In some arrangements, the thickness T13 of the bonding layer 313 may be equal to or greater than about 0.5 μm, for example, from about 0.5 μm to about 1 μm.

In some arrangements, the terminal 210 is electrically connected to the terminal 110 through the catalytic layer 311, the interlayer 312, and the bonding layer 313.

In some arrangements, the electrical connection structure 32E is over the terminal 120. In some arrangements, the electrical connection structure 32E includes an interlayer 322 and a bonding layer 323. The interlayer 322 may be referred to as an interconnection element, and the bonding layer 323 may be referred to as a bonding pad. In some arrangements, the interlayer 322 is configured to raise an elevation of the bonding layer 323 so as to increase a thickness T1 of the protective layer 40. Therefore, when a thinning operation (e.g., the CMP operation) is performed on the protective layer 40 to expose the bonding layer 323, with the thickness T1 of the protective layer 40 being relatively large, the processing window of the thinning operation (e.g., the CMP operation) for the protective layer 40 is enlarged, and thus the polishing rate or the grinding rate of the thinning operation can be relatively high without accidentally damaging the substrate 10. Therefore, the time of the thinning operation for the protective layer 40 can be reduced.

In some arrangements, the catalytic layer 321 is between the terminal 120 and the electrical connection structure 32E. In some arrangements, the catalytic layer 321 is between the terminal 120 and the interlayer 322. In some arrangements, the catalytic layer 321 is formed or directly contacts a surface 120a of the terminal 120. In some arrangements, a catalytic activity of the catalytic layer 321 is greater than a catalytic activity of the terminal 120. In some arrangements, the catalytic layer 321 has a catalytic activity for formation of the interlayer 322 greater than that of the terminal 120. In some arrangements, a rate of formation of the interlayer 322 on the catalytic layer 321 is greater than a rate of formation of the interlayer 322 on the terminal 120. In some arrangements, a ratio of the rate of formation of the interlayer 322 on the catalytic layer 321 to the rate of formation of the interlayer 322 on the terminal 120 is greater than 1, for example, from about 10 to about 1000, or from about 50 to about 800. In some arrangements, there is no seed layer between the catalytic layer 321 and the interlayer 322. The catalytic layer 321 may be formed by electroless plating. In some arrangements, the catalytic layer 321 is formed by electroless displacement deposition. In some arrangements, the catalytic layer 321 may be or include an electroless plating layer. In some arrangements, the catalytic layer 321 may be formed of or include silver (Ag), gold (Au), platinum (Pt), palladium (Pd), or a combination thereof. In some arrangements, the catalytic layer 321 may have a thickness T12 less than about 0.5 μm. When charges may accumulate on the edge of the surface 120a of the terminal 120, the interlayer 322 formed directly on the surface 120a of the terminal 120 may have a relatively large thickness on the edge of the surface 120a and a relatively small thickness on the center of the surface 120a, resulting in a non-uniform thickness of the interlayer 322. In some arrangements, the rate of formation of the interlayer 322 on the catalytic layer 321 is significantly greater than the rate of formation of the interlayer 322 on the terminal 120. The relatively high catalytic activity of the catalytic layer 321 dominates the formation mechanism of the interlayer 322, and the influence of the distribution of charges on the growth rate of the interlayer 322 is minimized or even can be omitted. Therefore, the interlayer 322 can be formed with a relatively large and uniform thickness. In some arrangements, the catalytic layer 321 is formed or deposited prior to or earlier than forming or depositing the interlayer 322. In some arrangements, the catalytic layer 321 is closer to the terminal 120 than the interlayer 322 is. With the above arrangements of the catalytic layer 321 and the interlayer 322, the aforementioned effects (e.g., reducing the time of the thinning operation, increasing the uniformity of the thickness of the interlayer 322, and etc.) can be achieved effectively.

In some arrangements, the interlayer 322 is at least partially between the catalytic layer 321 and the bonding layer 323 (or the bonding pad). In some arrangements, a width of the interlayer 322 is greater than a width of the catalytic layer 321. The interlayer 322 may be formed by electroless plating. In some arrangements, the interlayer 322 may be or include an electroless plating layer. In some arrangements, the interlayer 322 may be formed of or include gold (Au), aluminum (Al), copper (Cu), or an alloy thereof. In some arrangements, the interlayer 322 and the catalytic layer 321 include or are formed of different materials. In some arrangements, the interlayer 322 is referred to as a raised layer or a raised portion configured to increase a height or a thickness of the electrical connection structure 32E. In some arrangements, the interlayer 322 (or the raised layer) is configured to raise an elevation of the bonding layer 323 (or the bonding pad) with respect to the surface 101 of the substrate 10. In some arrangements, the interlayer 322 (or the raised layer) is configured to raise an elevation of the bonding layer 323 (or the bonding pad) to create an enlarged gap between the substrate 10 and the substrate 20 for accommodating the protective layer 40. In some arrangements, the interlayer 322 is configured to raise an elevation of the bonding layer 323 so as to increase the thickness T1 of the protective layer 40. Therefore, with the thickness T1 of the protective layer 40 being relatively large, the processing window of the thinning operation (e.g., the CMP operation) for the protective layer 40 is enlarged, and thus the polishing rate or the grinding rate of the thinning operation can be relatively high without accidentally damaging the substrate 10. Therefore, the time of the thinning operation for the protective layer 40 can be reduced. In some arrangements, the interlayer 322 (or the raised layer) is configured to define a thickness T1 of the protective layer 40 to prevent the dielectric layer 160 from being exposed by the protective layer 40. In some arrangements, the thickness T1 of the protective layer 40 is greater than a thickness T22 of the interlayer 322. In some arrangements, the thickness T22 of the interlayer 322 is equal to or greater than about 1 μm, for example, from about 1 μm to about 2 μm or from about 1 μm to about 1.5 μm. In some arrangements, the interlayers 312 and 322 have different widths.

In some arrangements, the bonding layer 323 is over the terminal 120. In some arrangements, the bonding layer 323 is between the terminal 120 and the terminal 220. The bonding layer 323 may be formed by electroless plating. In some arrangements, the bonding layer 323 may be or include an electroless plating layer. In some arrangements, the bonding layer 323 may be formed of or include a material having a melting point lower than that of the terminal 120. The bonding layer 323 may be referred to as a low melting point conductive layer. In some arrangements, the bonding layer 323 may be formed of or include Ag or an alloy thereof. In some arrangements, the thickness T21 of the catalytic layer 321 is less than a thickness T23 of the bonding layer 323. In some arrangements, the thickness T23 of the bonding layer 323 may be equal to or greater than about 0.5 μm, for example, from about 0.5 μm to about 1 μm.

In some arrangements, the terminal 220 is electrically connected to the terminal 120 through the catalytic layer 321, the interlayer 322, and the bonding layer 323.

In some arrangements, the catalytic layers 311 and 321 collectively construct a catalytic structure including portions (e.g., the catalytic layers 311 and 321) separated from each other. For example, the catalytic structure includes a portion (e.g., the catalytic layer 311) between the terminal 110 and the electrical connection structure 31E and a portion (e.g., the catalytic layer 321) between the terminal 120 and the electrical connection structure 32E. In some arrangements, the catalytic structure is configured to reduce a difference in a thickness of the electrical connection structure 31E and a thickness of the electrical connection structure 32E. In some arrangements, the catalytic structure is configured to reduce a difference in a thickness T12 of the interlayer 312 and a thickness T22 of the interlayer 322. In some arrangements, the difference in the thickness T12 of the interlayer 312 and the thickness T22 of the interlayer 322 is less than a thickness of the bonding layer 313. In some arrangements, a catalytic activity of the catalytic structure is greater than a catalytic activity of the terminal 110 or a catalytic activity of the terminal 120. In some arrangements, a catalytic activity of the catalytic structure is greater than a catalytic activity of the terminal 110 and a catalytic activity of the terminal 120. In some arrangements, there is no seed layer between the catalytic structure and both of the terminals 110 and 120.

The protective layer 40 may be disposed over the first dielectric layer 160. In some arrangements, the protective layer 40 may be referred to as a pre-bonding layer or an adhesion layer in a hybrid-bond structure to adhere the substrates 10 and 20 of the bonding structure 1A. In some arrangements, the protective layer 40 encapsulates the catalytic structure, the electrical connection structure 31E, and the electrical connection structure 32E. In some arrangements, the protective layer 40 encapsulates the catalytic layer 311, the interlayer 312, and the bonding layer 313. In some arrangements, the protective layer 40 encapsulates the catalytic layer 321, the interlayer 322, and the bonding layer 323. In some arrangements, a thickness T1 of the protective layer 40 is greater than a sum of a thickness T31 of the catalytic layer 311 and a thickness T12 of the interlayer 312. In some arrangements, the thickness T1 of the protective layer 40 is equal to or greater than about 2 μm. In some arrangements, a surface 313a of the bonding layer 313 substantially aligns with a surface 40a of the protective layer 40. The protective layer 40 may include an organic material, a solder mask, polyimide (PI), an ABF, one or more molding compounds, one or more pre-impregnated composite fibers (e.g., a pre-preg material), a semiconductor oxide (e.g., SiOx), any combination thereof, or the like. The protective layer 40 may be or include a dielectric structure. The protective layer 40 may be formed of or include an organic dielectric material.

The conductive layers, pads, pillars, and/or vias and the terminals may independently include a conductive material such as a metal or metal alloy. Examples include Au, Ag, Al, Cu, or an alloy thereof. The dielectric layers may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

In some cases where the substrate 10 may be hybrid-bonded to the substrate 20 through at least terminals 110 and 210 and the protective layer 40, the protective layer 40 may be formed on the terminal 110, an opening may be formed in the protective layer 40 to expose the terminal 110, and a conductive adhesion layer may be further formed in the opening of the protective layer 40 and on the terminal 110 so as to form a hybrid-bond structure including the protective layer 40 and the conductive adhesion layer that bonds the substrates 10 and 20. However, in order to avoid the opening formed in the protective layer 40 being misaligned with the terminal 110 underneath, the size of the opening is enlarged to increase the processing window of the bonding process, and thus the size of the bonding structure is undesirably increased. To solve the above issue, instead of forming the protective layer 40 and then depositing the conductive adhesion layer in the opening of the protective layer 40, the bonding process may alternatively include forming the conductive adhesion layer on the terminal 110 and then forming a protective material layer to cover the conductive adhesion layer followed by thinning the protective material layer to form the protective layer 40. The conductive adhesion layer may be formed by electroless plating (e.g., electroless displacement deposition) and thus have a relatively small thickness, and a thinning operation may be performed on the protective material layer to form the protective layer 40 and expose the conductive adhesion layer from the protective layer 40 for subsequent bonding. However, in order to expose the relatively thin conductive adhesion layer, the as-formed protective layer 40 may become too thin after the thinning operation, such that the dielectric layer 160 may be exposed by the protective layer 40, and the remained amount of the protective layer 40 is insufficient to expand to a desired volume so as to fill the gap between the substrates 10 and 20.

According to some arrangements of the present disclosure, the interlayer 312 is formed between the terminal 110 and the bonding layer 313 and is configured to raise an elevation of the bonding layer 313. As such, the protective layer 40 may have an increased thickness T1 defined by the interlayer 312. Therefore, even with the protective layer 40 formed by a thinning operation by removing a portion of a protective material layer to expose the bonding layer 313, since the elevation of the bonding layer 313 is raised, the thickness T1 of the protective layer 40 is defined by the bonding layer 313 and thus is increased by the interlayer 312. Accordingly, the dielectric layer 160 can be prevented from being exposed by the protective layer 40, the remained amount of the protective layer 40 after the thinning operation is sufficient to expand to a desired volume so as to fill the gap between the substrates 10 and 20, and thus a hybrid-bond structure including the protective layer 40 may be formed to bond the substrates 10 and 20.

In addition, because the interlayer 312 may be formed by electroless plating, the distribution of charges may influence the growth rate of the interlayer 312. When the distribution of charges dominates the electroless plating of the interlayer 312, since charges may accumulate on the edge of the surface 110a of the terminal 110, the interlayer 312 formed directly on the surface 110a of the terminal 110 may have a relatively large thickness on the edge of the surface 110a and a relatively small thickness on the center of the surface 110a, resulting in a non-uniform thickness of the interlayer 312. In contrast, according to some arrangements of the present disclosure, the interlayer 312 is formed on the catalytic layer 311 instead of on the terminal 110, and the catalytic activity of the catalytic layer 311 is greater than a catalytic activity of the terminal 110. Accordingly, the rate of formation of the interlayer 312 on the catalytic layer 311 is significantly greater than the rate of formation of the interlayer 312 on the terminal 110. The relatively high catalytic activity of the catalytic layer 311 dominates the formation mechanism of the interlayer 312, and the influence of the distribution of charges on the growth rate of the interlayer 312 is minimized or even can be omitted. Therefore, the interlayer 312 can be formed with a relatively large and uniform thickness.

Moreover, according to some arrangements of the present disclosure, since the catalytic layer 311 serves to increase the activity for forming the interlayer 312, the thickness of the catalytic layer 311 can be relatively thin, such that overconsumption of the terminal 110 can be further prevented.

FIG. 1B is a cross-section of a bonding structure 1B in accordance with some arrangements of the present disclosure. The bonding structure 1B illustrated in FIG. 1B is similar to that in FIG. 1A, with differences therebetween as follows.

The electrical connection structure 31E may include a catalytic layer 311, an interlayer 312, and a bonding layer 313. In some arrangements, the bonding layer 313 covers a sidewall (e.g., surface 312b) of the interlayer 312. In some arrangements, a width of the bonding layer 313 is greater than a width of the interlayer 312. In some arrangements, a roughness of an interface (e.g., the surface 313b) between the protective layer 40 and the bonding layer 313 is greater than a roughness of a top surface (e.g., the surface 313a) of the bonding layer 313. In some arrangements, a roughness of a sidewall (e.g., the surface 313b) of the bonding layer 313 is greater than a roughness of the sidewall (e.g., the surface 312b) of the interlayer 312. In some arrangements, the bonding layer 313 includes Ag layer formed of stacked Ag whiskers, and thus the sidewall of the bonding layer 313 has a relatively large roughness. In some arrangements, the term “roughness” may refer to “surface roughness.” In some arrangements, the interlayer 312 covers the catalytic layer 311. In some arrangements, a width of the interlayer 312 is greater than a width of the catalytic layer 311.

The electrical connection structure 32E may include a catalytic layer 321, an interlayer 322, and a bonding layer 323. In some arrangements, the bonding layer 323 covers a sidewall (e.g., surface 322b) of the interlayer 322. In some arrangements, a width of the bonding layer 323 is greater than a width of the interlayer 322. In some arrangements, a roughness of an interface (e.g., the surface 323b) between the protective layer 40 and the bonding layer 323 is greater than a roughness of a top surface (e.g., the surface 323a) of the bonding layer 323. In some arrangements, a roughness of a sidewall (e.g., the surface 323b) of the bonding layer 323 is greater than a roughness of the sidewall (e.g., the surface 322b) of the interlayer 322. In some arrangements, the bonding layer 323 includes Ag layer formed of stacked Ag whiskers, and thus the sidewall of the bonding layer 323 has a relatively large roughness. In some arrangements, the interlayer 322 covers the catalytic layer 321. In some arrangements, a width of the interlayer 322 is greater than a width of the catalytic layer 321.

FIG. 1C is a cross-section of a pre-bonding structure 1000 in accordance with some arrangements of the present disclosure. In some arrangements, the bonding structure 1A illustrated in FIG. 1A includes the pre-bonding structure 1000 illustrated in FIG. 1C.

In some arrangements, the protective layer 40 (or the pre-bonding layer) encapsulates the bonding layer 313 and exposes a top surface (e.g., the surface 313a) of the bonding layer 313. In some arrangements, the interlayer 312 (also referred to as “the raised layer”) is adhered to the bonding layer 313 and defines a thickness T1 of the protective layer 40 (or the pre-bonding layer). In some arrangements, the thickness T1 is configured to prevent the substrate 10 from being exposed by the protective layer 40 (or the pre-bonding layer) during a thinning operation for the protective layer 40 (or the pre-bonding layer). In some arrangements, the thickness T1 is equal to or greater than 2 μm. In some arrangements, a range of the thickness T1 is from 2 μm to 5 μm. In some arrangements, the thickness T1 of the protective layer 40 (or the pre-bonding layer) is greater than a thickness of the terminal 110 of the substrate 10. When a chemical mechanical polishing (CMP) operation is performed on the protective layer 40, the terminal 110 may be damaged by the CMP operation if the protective layer 40 is removed to expose the substrate 10. In some arrangements, the terminal 110 is relatively thick to tolerate the loss in the thickness without being entirely removed during the CMP operation. In some arrangements, the terminal 110 is relatively thin and may be entirely removed by the CMP operation, and thus the thickness T1 of the protective layer 40 (or the pre-bonding layer) being greater than the thickness of the terminal 110 of the substrate 10 can protect the terminal 110 from being damaged or removed.

In some arrangements, the interlayer 312 (or the raised layer) is configured to reduce a time of the thinning operation for the protective layer 40 (or the pre-bonding layer). In some arrangements, the interlayer 312 is configured to raise an elevation of the bonding layer 313 so as to increase the thickness T1 of the protective layer 40. Therefore, with the thickness T1 of the protective layer 40 being relatively large, the processing window of the thinning operation (e.g., the CMP operation) for the protective layer 40 is enlarged, and thus the polishing rate or the grinding rate of the thinning operation can be relatively high without accidentally damaging the substrate 10. Therefore, the time of the thinning operation for the protective layer 40 can be reduced.

FIG. 1D is a cross-section of a pre-bonding structure 1000A in accordance with some arrangements of the present disclosure.

In some arrangements, a top surface (e.g., the surface 313a) of the bonding layer 313 includes a curved surface (e.g., a concave surface). The concave top surface of the bonding layer 313 may be resulted from a dishing effect of a CMP operation performed on the bonding layer 313 and the protective layer 40. In some arrangements, the bottom surface 313c of the bonding layer 313 is smoother than the top surface (e.g., the surface 313a) of the bonding layer 313. In some arrangements, the bottom surface 313c of the bonding layer 313 is flatter than the top surface (e.g., the surface 313a) of the bonding layer 313. In some arrangements, the bonding layer 313 is spaced apart from the terminal 110. In some arrangements, a melting point of the bonding layer 313 is lower than a melting point of the terminal 110. In some arrangements, a top end 313e of the lateral surface (e.g., the surface 313b) of the bonding layer 313 is substantially aligned with a top surface (e.g., the surface 40a) of the protective layer 40 (or the pre-bonding layer). In some arrangements, a bottom surface 313c of the bonding layer 313 is flatter than a top surface (e.g., the surface 313a) of the bonding layer 313.

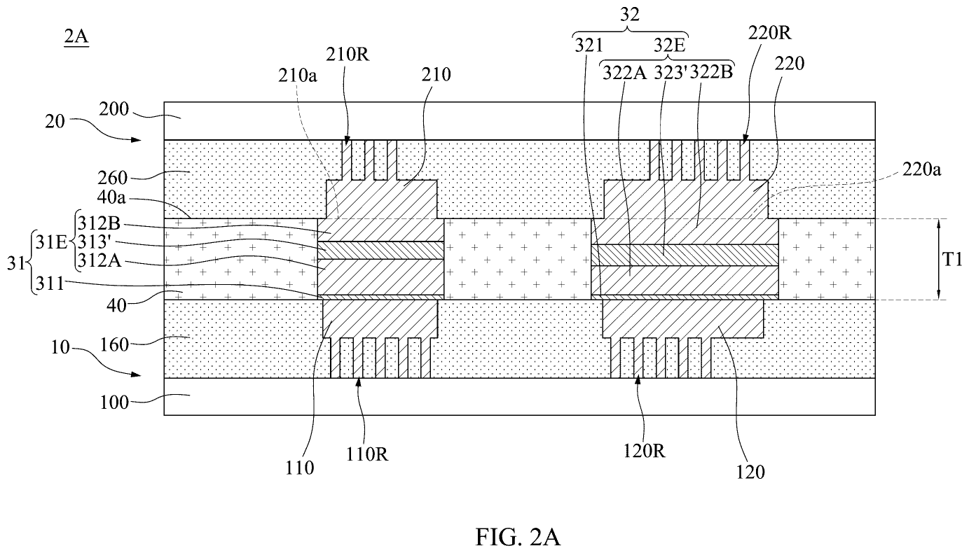

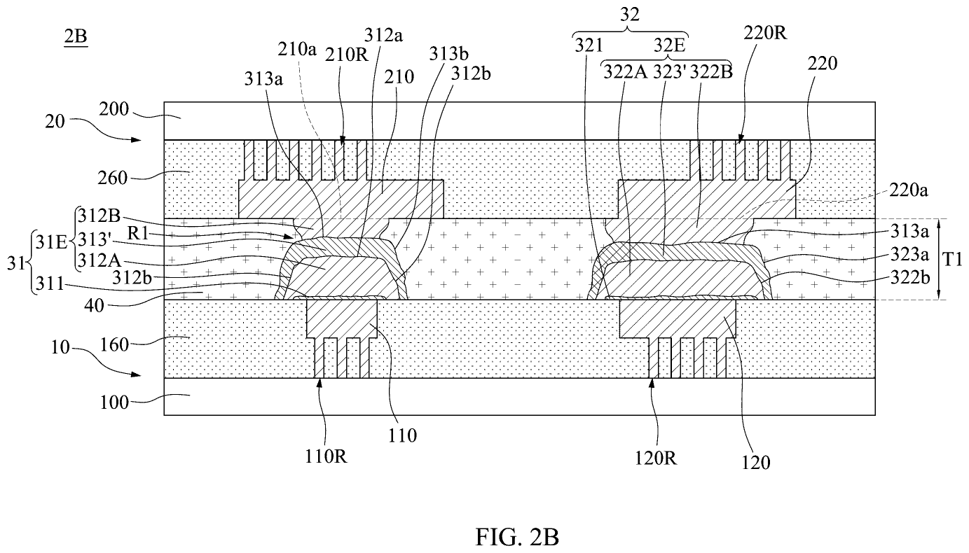

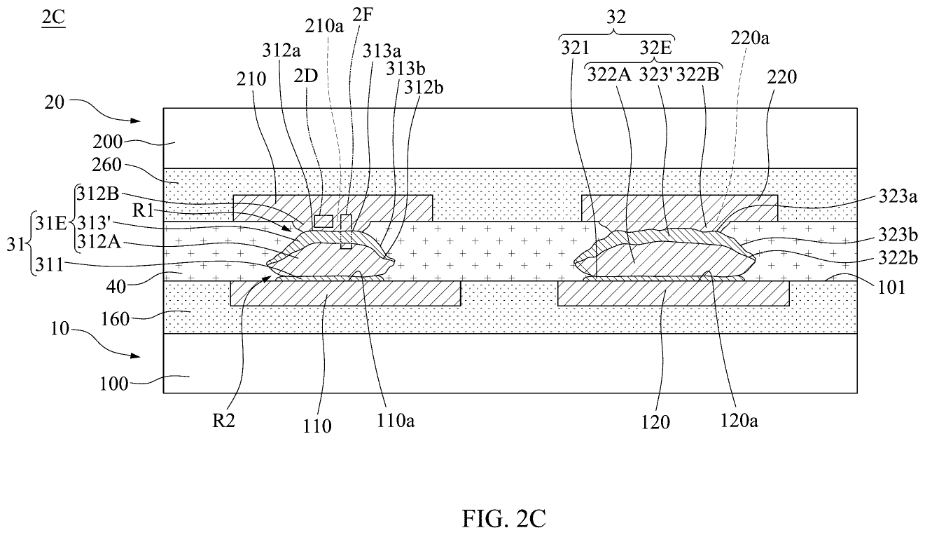

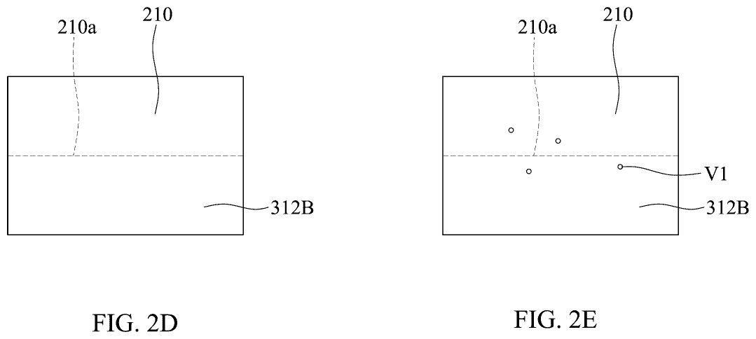

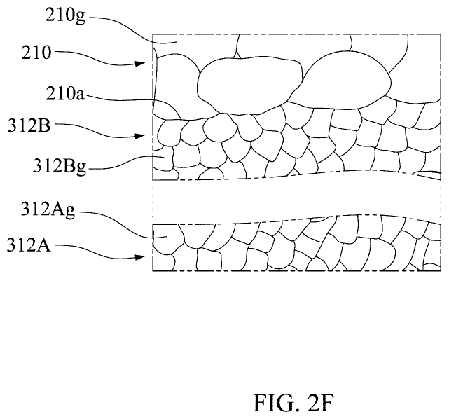

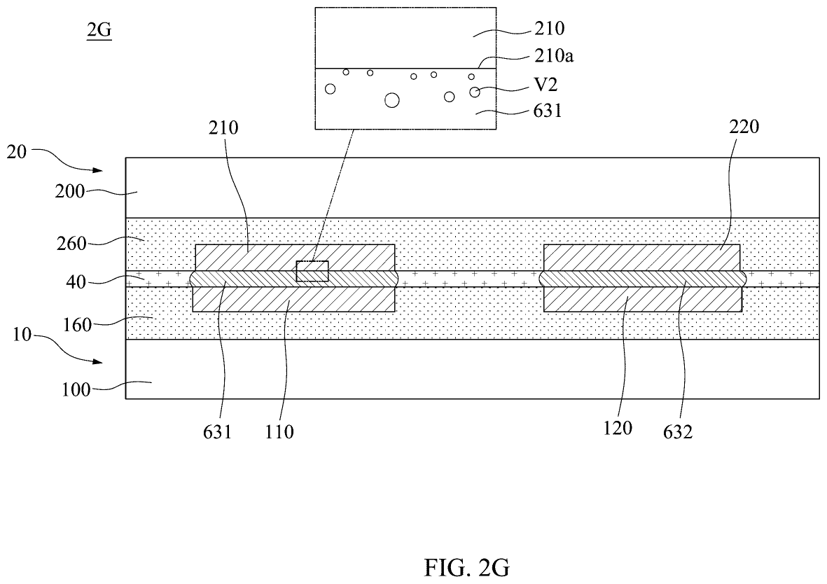

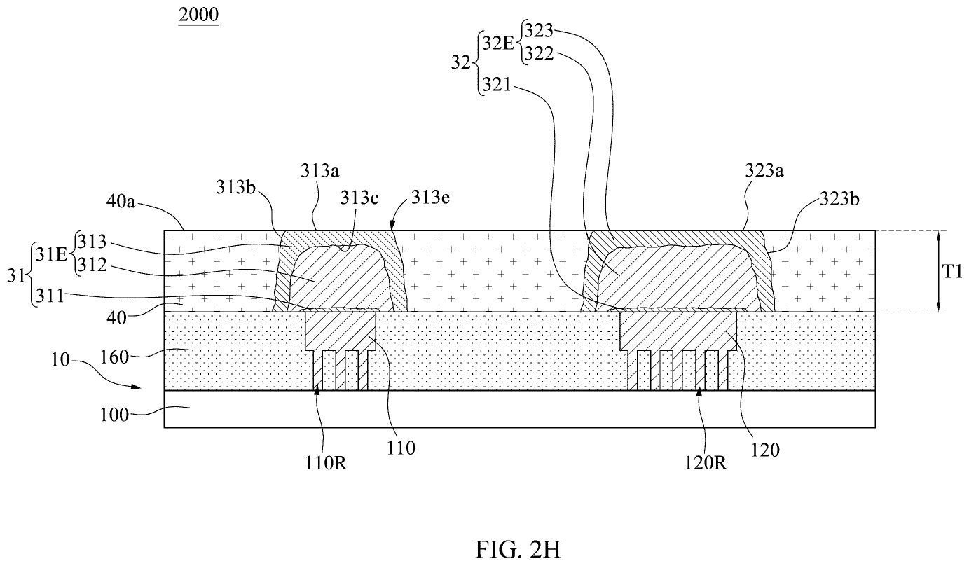

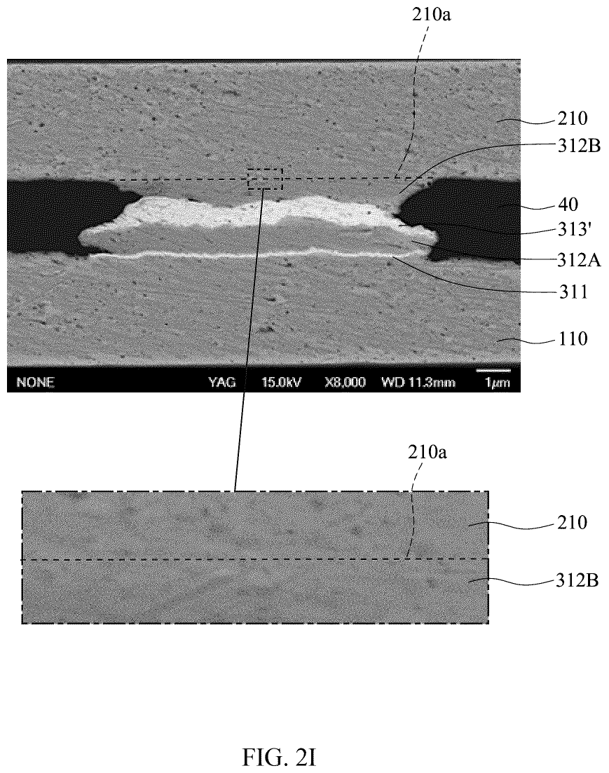

FIG. 2A is a cross-section of a bonding structure 2A in accordance with some arrangements of the present disclosure. The bonding structure 2A illustrated in FIG. 2A is similar to that in FIG. 1A, with differences therebetween as follows.

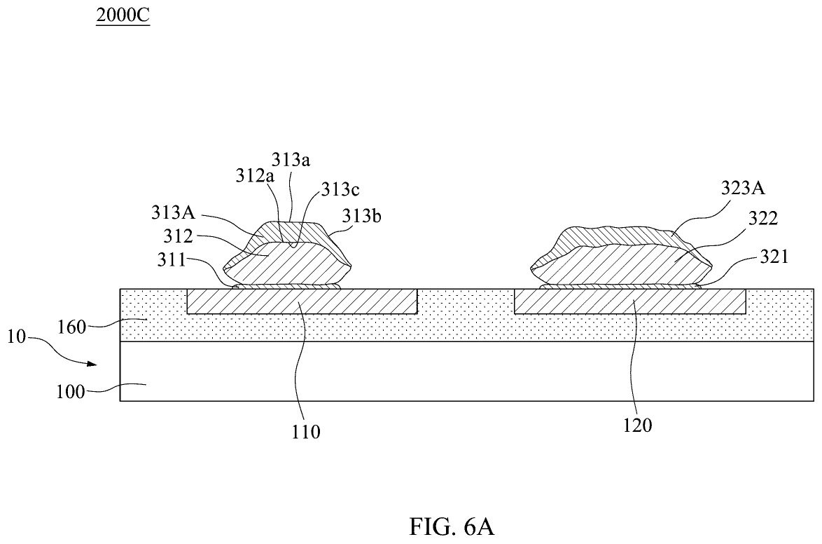

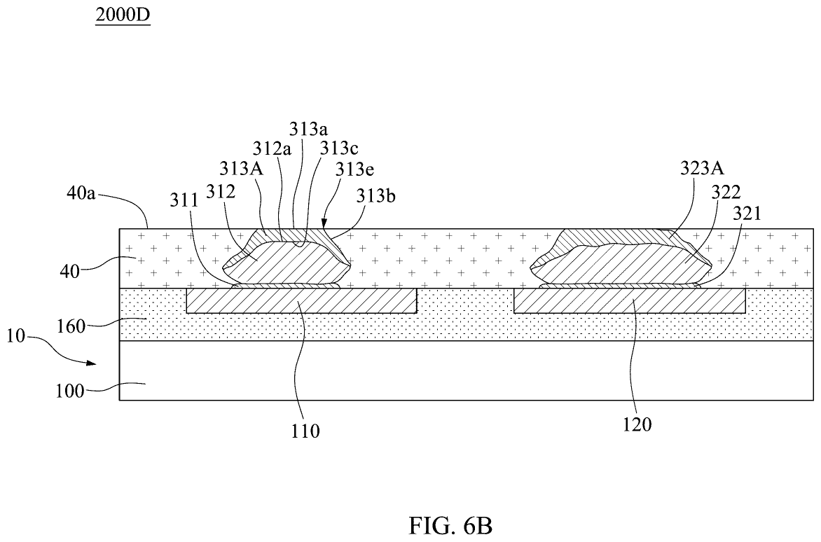

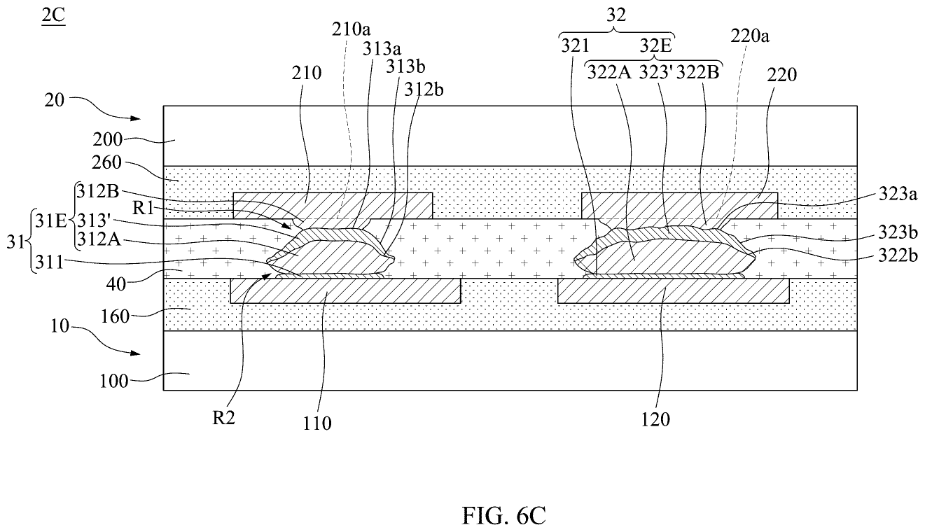

In some arrangements, the interlayer (also referred to as “the interconnection element” or “the high melting point conductive layer”) of the electrical connection structure 31E includes a raised portion 312A (also referred to as “a lower portion”) between the terminal 110 and the bonding layer 313′ and a diffused portion 312B (also referred to as “an upper portion”) between the bonding layer 313′ and the terminal 210. The diffused portion 312B may be or include a metal diffused portion. In some arrangements, the metal diffused portion (or the diffused portion 312B) is originated from the raised portion 312A. In some arrangements, an interface 210a is formed between the diffused portion 312B and the terminal 210. In some arrangements, the boding layer 313′ is closer to the substrate 20 than to the substrate 10. In some arrangements, the diffused portion 312B directly contacts the terminal 210 with an interface 210a when the diffused portion 312B and the terminal 210 include or are formed of different materials. In some arrangements, there is substantially no void at the interface 210a. In some arrangements, the diffused portion 312B directly contacts the terminal 210 without an interface (e.g., the interface 210a) formed between the diffused portion 312B and the terminal 210. The term “without an interface” used herein indicates that no interface may be observed through electron microscope technology (e.g. SEM or AFM). In some arrangements, the diffused portion 312B directly contacts or connects to the bonding layer 313′ and the terminal 210 and is configured to increase a bonding strength between the bonding layer 313′ and the terminal 210. In some arrangements, the raised portion 312A and the diffused portion 312B include or are formed of the same material. In some arrangements, the raised portion 312A and the diffused portion 312B may be formed of or include a material having a melting point higher than that of the bonding layer 313′. In some arrangements, the raised portion 312A and the diffused portion 312B collectively may be referred to as a high melting point conductive layer. In some arrangements, an interface (e.g., the interface 210a) between the substrate 20 and the high melting point conductive layer is substantially aligned (or co-level) with an interface (e.g., the surface 40a) between the protective layer 40 and the substrate 20. In some arrangements, during a thermal compression bonding (TCB) process, a portion of the interlayer 312 (e.g., metal molecules of the interlayer 312) may diffuse and penetrate the bonding layer (e.g., the bonding layer 313A illustrated in FIG. 6B) to form a raised portion 312A and a diffused portion 312B spaced apart from each other. In some arrangements, with the formation of the raised portion 312A and the diffused portion 312B, the metal molecules of the bonding layer (e.g., the bonding layer 313A illustrated in FIG. 6B) may diffuse toward the substrate 10 to form the bonding layer 313′. In some arrangements, a lattice size of the metal diffused portion is less than a lattice size of the terminal 110 and a lattice size of the terminal 210. In some arrangements, grains of the metal diffused portion contact at least one of grains of the terminal 210, and a grain size of the metal diffused portion is less than a grain size of the terminal 110 and a grain size of the terminal 210. In some arrangements, the lattice size or the grain size of the metal diffused portion (e.g., the diffused portion 312B) substantially matches the lattice size or the grain size of the raised portion 312A. In some arrangements, the lattice size or the grain size of the metal diffused portion (e.g., the diffused portion 312B) is substantially consistent with the lattice size or the grain size of the raised portion 312A.

In some arrangements, the interlayer (or the high melting point conductive layer) of the electrical connection structure 32E includes a raised portion 322A between the terminal 120 and the bonding layer 323′ and a diffused portion 322B between the bonding layer 323′ and the terminal 220. In some arrangements, the diffused portion 322B directly contacts the terminal 220 with an interface 220a when the diffused portion 322B and the terminal 220 include or are formed of different materials. In some arrangements, there is substantially no void at the interface 220a. In some arrangements, the diffused portion 322B directly contacts the terminal 220 without an interface (e.g., the interface 220a) formed between the diffused portion 322B and the terminal 220. In some arrangements, the diffused portion 322B directly contacts the bonding layer 323′ and the terminal 220 and is configured to increase a bonding strength between the bonding layer 323′ and the terminal 220. In some arrangements, the raised portion 322A and the diffused portion 322B include or are formed of the same material. In some arrangements, the raised portion 312A and the raised portion 322A have different thicknesses. In some arrangements, the diffused portion 312B and the diffused portion 322B have different thicknesses.

FIG. 2B is a cross-section of a bonding structure 2B in accordance with some arrangements of the present disclosure. The bonding structure 2B illustrated in FIG. 2B is similar to that in FIG. 1A, with differences therebetween as follows.

In some arrangements, the bonding layer 313′ covers a sidewall (e.g., surface 312b) of the raised portion 312A. In some arrangements, a width of the bonding layer 313′ is greater than a width of the raised portion 312A. In some arrangements, a roughness of a sidewall (e.g., the surface 313b) of the bonding layer 313′ is greater than a roughness of the sidewall (e.g., the surface 312b) of the raised portion 312A. In some arrangements, the raised portion 312A covers the catalytic layer 311. In some arrangements, a width of the raised portion 312A is greater than a width of the catalytic layer 311. In some arrangements, the raised portion 312A tapers toward the bonding layer 313′. In some arrangements, the diffused portion 312B tapers toward the bonding layer 313′. In some arrangements, a width of the raised portion 312A is greater than a width of the diffused portion 312B. In some arrangements, in a cross-sectional view, an interface (e.g., the surfaces 313a and 313b) between the diffused portion 312B and the bonding layer 313′ is at least partially substantially conformal with an interface (e.g., the surfaces 312a and 312b) between the raised portion 312A and the bonding layer 313′.

In some arrangements, the bonding layer 323′ covers a sidewall of the raised portion 322A. In some arrangements, a width of the bonding layer 323′ is greater than a width of the raised portion 322A. In some arrangements, a roughness of a sidewall of the bonding layer 323′ is greater than a roughness of the sidewall of the raised portion 322A. In some arrangements, the raised portion 322A covers the catalytic layer 321. In some arrangements, a width of the raised portion 322A is greater than a width of the catalytic layer 321. In some arrangements, the raised portion 322A tapers toward the bonding layer 323′. In some arrangements, the diffused portion 322B tapers toward the bonding layer 323′. In some arrangements, a width of the raised portion 322A is greater than a width of the diffused portion 322B. In some arrangements, an interface between the diffused portion 322B and the bonding layer 323′ is at least partially substantially conformal with an interface between the raised portion 322A and the bonding layer 323′.

In some arrangements, the protective layer 40 encapsulates the bonding layer 313′ and the interlayer (or the interconnection element) including the raised portion 312A and the diffused portion 312B. In some arrangements, a lateral sidewall of the diffused portion 312B and a lateral sidewall of the bonding pad 313′ defines a recess R1 (also referred to as “a cavity”), and the protection layer 40 includes a portion filled in the recess R1.

FIG. 2C is a cross-section of a bonding structure 2C in accordance with some arrangements of the present disclosure. The bonding structure 2C illustrated in FIG. 2C is similar to that in FIG. 1A, with differences therebetween as follows.

In some arrangements, the catalytic layer 311 is between the raised portion 312A and the terminal 110, and a portion of the raised portion 312A is spaced apart from a portion of the catalytic layer 311 by a recess R2 (also referred to as “a cavity”). In some arrangements, the protective layer 40 includes a portion filled in the recess R2. In some arrangements, a width of the catalytic layer 311 is less than a width of the terminal 110. In some arrangements, a top surface (e.g., the surface 110a) of the terminal 110 is substantially aligned with an interface (e.g., the surface 101 between the protective layer 40 and the substrate 10. In some arrangements, the diffused portion 312B tapers toward the substrate 10. In some arrangements, the raised portion 312A tapers toward the substrate 20.

FIG. 2D is a cross-section of a portion of a bonding structure 2C in accordance with some arrangements of the present disclosure. In some arrangements, FIG. 2D is a cross-section of a portion 2D of the bonding structure 2C illustrated in FIG. 2C.

In some arrangements, there is substantially no void at the interface 210a between the terminal 210 and the diffused portion 312B.

FIG. 2E is a cross-section of a portion of a bonding structure 2C in accordance with some arrangements of the present disclosure. In some arrangements, FIG. 2E is a cross-section of a portion 2D of the bonding structure 2C illustrated in FIG. 2C.

In some arrangements, a few voids V1 are formed at the interface 210a between the terminal 210 and the diffused portion 312B.

FIG. 2F is a cross-section of a portion of a bonding structure 2C in accordance with some arrangements of the present disclosure. In some arrangements, FIG. 2F is a cross-section of a portion 2F of the bonding structure 2C illustrated in FIG. 2C.

In some arrangements, grains 312Bg of the diffused portion 312B contact at least one of grains 210g of the terminal 210, and a grain size of the diffused portion 312B is less than a grain size of the terminal 110 and a grain size of the terminal 210. In some arrangements, a grain 312Bg of the diffused portion 312B is within a vertical protection of a grain 210g of the terminal 210 of the substrate 20. In some arrangements, a grain 312Ag of the raised portion 312A is within a vertical protection of a grain 210g of the terminal 210 of the substrate 20. In some arrangements, the grain size of the diffused portion 312B substantially matches the grain size of the raised portion 312A. In some arrangements, the grain size of the diffused portion 312B is substantially consistent with the grain size of the raised portion 312A.

In some arrangements, some grains 312Bg of the diffused portion 312B directly contact the terminal 210, some grains 210g of the terminal 210 directly contact the diffused portion 312B, and a quantity of the grains 312Bg that contact the terminal 210 is greater than a quantity of the grains 210g that contact the diffused portion 312B. In some arrangements, similar to the above, some grains 312Ag of the raised portion 312A directly contact the terminal 110, some grains of the terminal 110 directly contact the raised portion 312A, and a quantity of the grains 312Ag that contact the terminal 110 is greater than a quantity of the grains of the terminal 110 that contact the raised portion 312A.

FIG. 2G is a cross-section of a bonding structure 2G in accordance with some arrangements of the present disclosure. The bonding structure 2G illustrated in FIG. 2G is similar to that in FIG. 2A, FIG. 2B, or FIG. 2C, with differences therebetween as follows.

In some arrangements, the terminal 210 is bonded to the terminal 110 by a bonding layer 631. In some arrangements, the terminal 220 is bonded to the terminal 120 by a bonding layer 632. The bonding layers 631 and 632 may be formed of or include a conductive material similar to that of the bonding layer 331′ and/or the bonding layer 332′. In some arrangements, voids V2 are formed at the interface 210a between the terminal 210 and the bonding layer 631. In some arrangements, a number of the voids V2 is greater than a number of the voids V1. In some arrangements, a distribution density of the voids V2 is greater than a distribution density of the voids V1.

FIG. 2H is a cross-section of a pre-bonding structure 2000 in accordance with some arrangements of the present disclosure.

In some arrangements, the bottom surface 313c of the bonding layer 313′ is smoother than the top surface (e.g., the surface 313a) of the bonding layer 313′. In some arrangements, the bottom surface 313c of the bonding layer 313′ is flatter than the top surface (e.g., the surface 313a) of the bonding layer 313′. In some arrangements, a roughness of the bottom surface 313c of the bonding layer 313′ is less than a roughness of the top surface (e.g., the surface 313a) of the bonding layer 313′. In some arrangements, the interlayer 312 (or the raised layer) is under the bonding layer 313′, and a top surface (e.g., the surface 312a) of the interlayer 312 (or the raised layer) is closer to the top surface (e.g., the surface 40a) of the protective layer 40 (or the pre-bonding layer) than to the terminal 110. In some arrangements, the interlayer 312 (or the raised layer) is spaced apart from the protective layer 40 (or the pre-bonding layer).

FIG. 2I is a scanning electron microscope (SEM) image of a cross-section of a bonding structure in accordance with some arrangements of the present disclosure. In some arrangements, FIG. 2I shows a SEM image of a portion of the cross-section illustrated in FIG. 2C. In some arrangements, FIG. 2I further shows a SEM image of the cross-section illustrated in FIG. 2D.

As shown in FIG. 21, in some arrangements, there is substantially no void at the interface 210a between the terminal 210 and the diffused portion 312B.

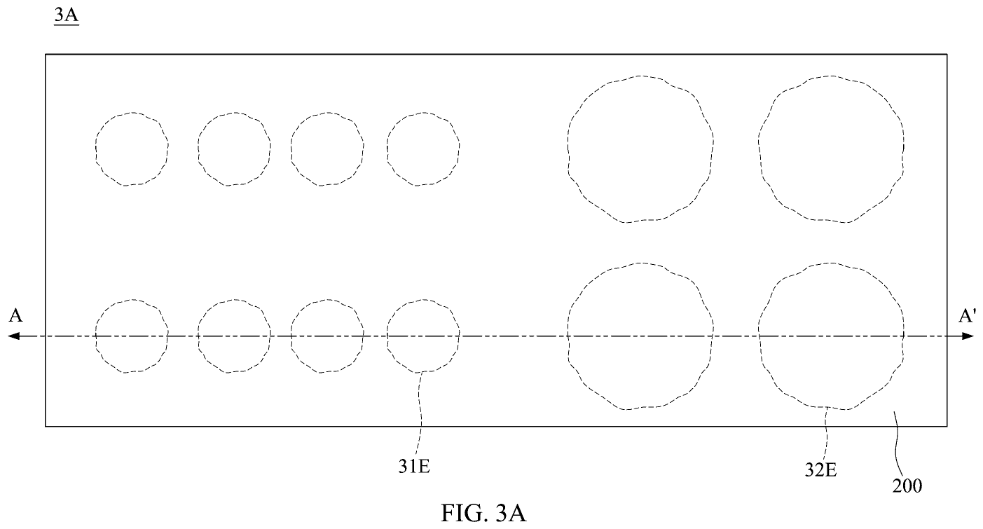

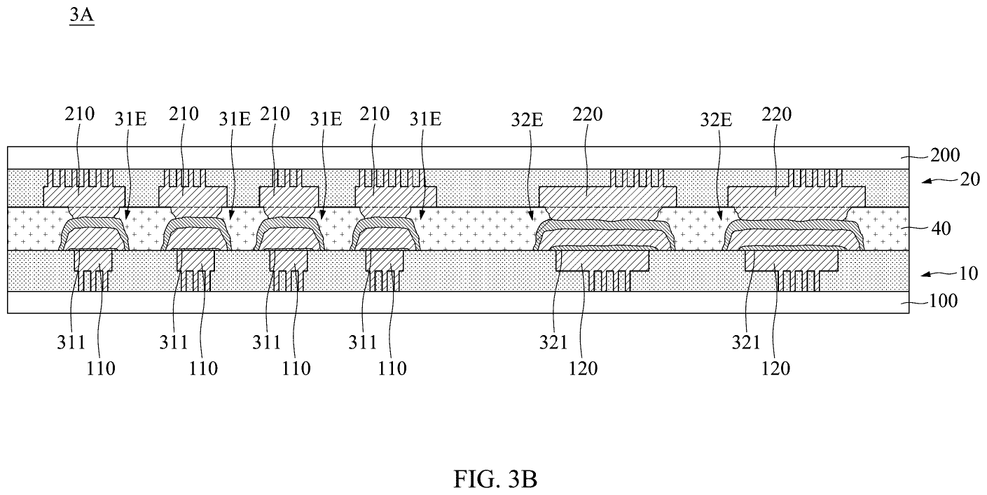

FIG. 3A is a top view of a bonding structure 3A in accordance with some arrangements of the present disclosure. FIG. 3B is a cross-section of a bonding structure 3A in accordance with some arrangements of the present disclosure. In some arrangements, FIG. 3B is a cross-section of a portion of the bonding structure 3A illustrated in FIG. 3A. It should be noted that some elements are not shown in FIG. 3A for clarity.

In some arrangements, the bonding structure 3A includes a plurality of electrical connection structures 31E and a plurality of electrical connection structures 32E. In some arrangements, a pitch of the electrical connection structures 31E is different from a pitch of the electrical connection structures 32E. The pitch may be less than about 10 μm, from about 10 μm to about 45 μm, or from about 10 μm to about 30 μm. The width of the electrical connection structure may be equal to or less than about 3 μm, from about 3 μm to about 25 μm, or from about 3 μm to about 10 μm. In some arrangements, an area of the electrical connection structure 31E is less than an area of the electrical connection structure 32E from a top view perspective. In some arrangements, a distribution density of the electrical connection structures 31E is greater than a distribution density of the electrical connection structures 32E.

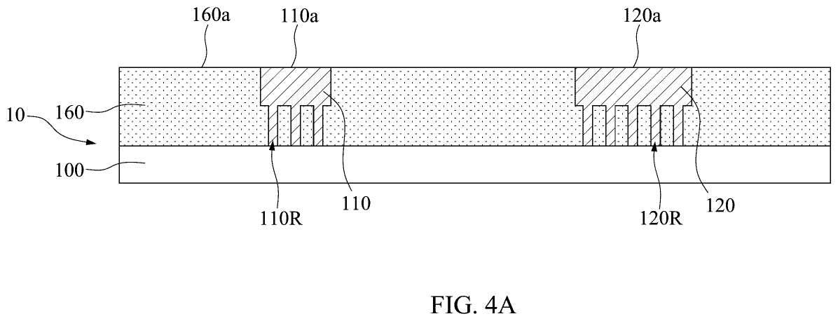

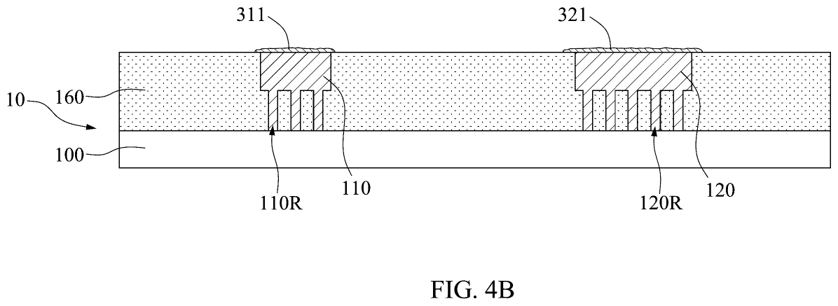

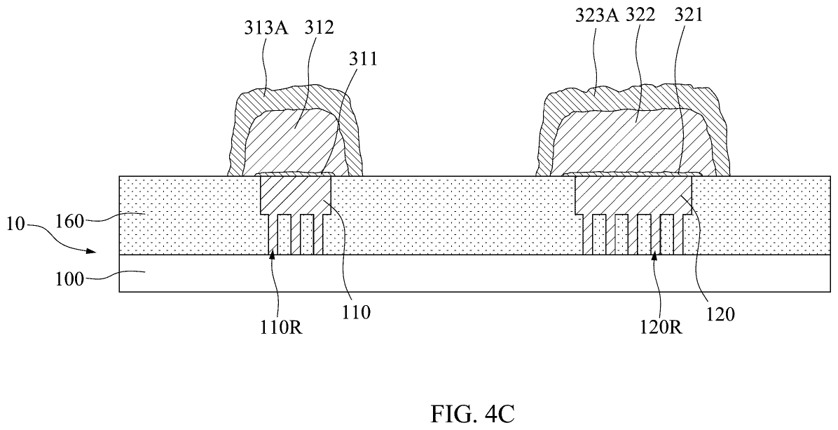

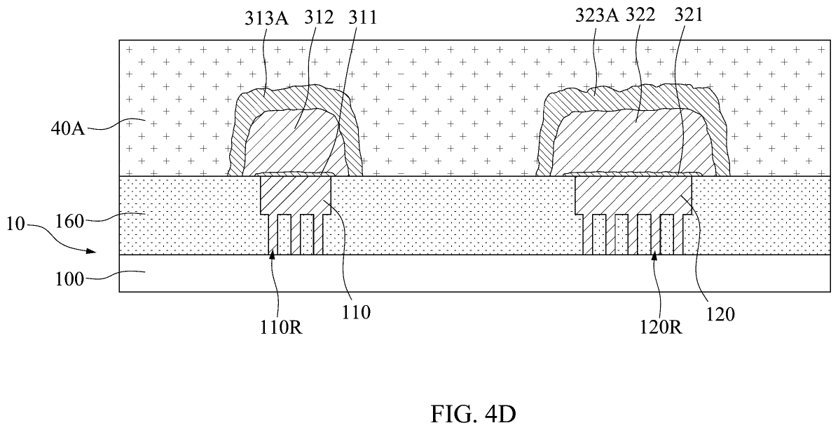

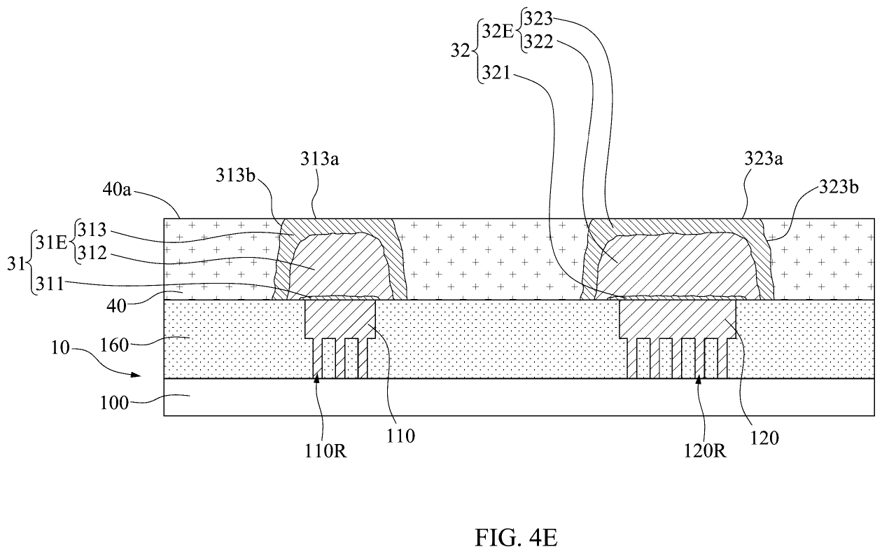

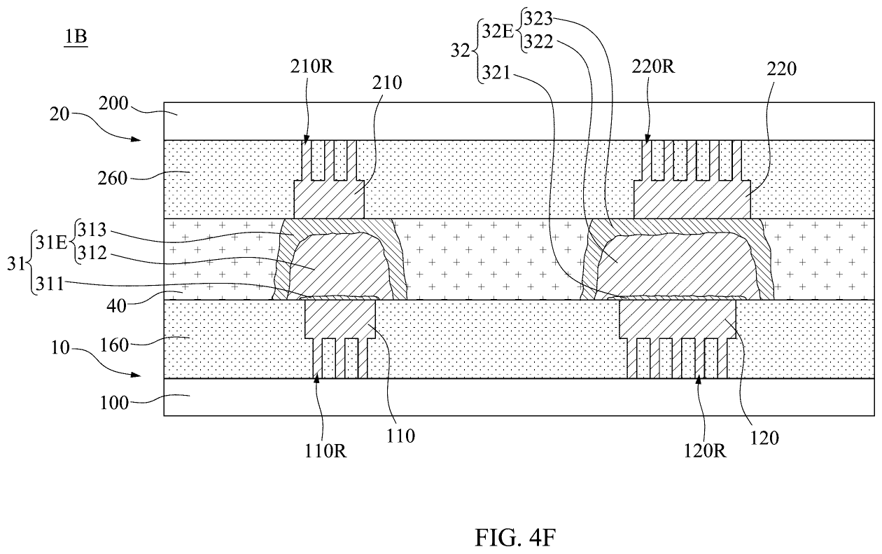

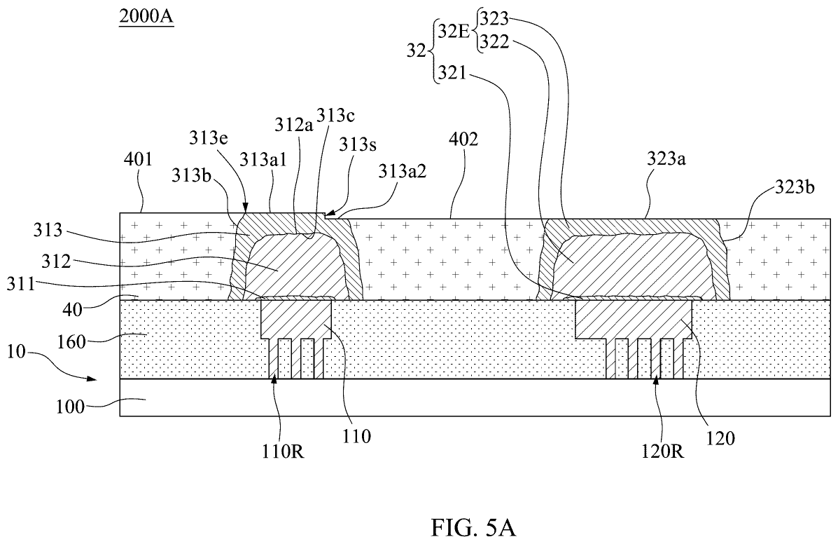

FIG. 4A, FIG. 4B, FIG. 4C, FIG. 4D, FIG. 4E, and FIG. 4F illustrate various stages of an exemplary method for manufacturing a bonding structure 1B in accordance with some embodiments of the present disclosure.

Referring to FIG. 4A, a substrate 10 including a base layer 100, terminals 110 and 120, interconnection elements 110R and 120R, and a dielectric layer 160 may be provided. In some arrangements, a planarization operation (e.g., a chemical mechanical polishing operation) may be performed to planarize the entire top surface of the structure. In some arrangements, the planarization operation may remove portions of the terminals 110 and 120 and the dielectric layer 160 to expose top surfaces 110a and 120a of the terminals 110 and 120. In some arrangements, the top surfaces 110a and 120a of the terminals 110 and 120 are substantially aligned with or coplanar with the top surface 160a of the dielectric layer 160.

Referring to FIG. 4B, a catalytic layer 311 may be formed on the top surface 110a of the terminal 110, and a catalytic layer 321 may be formed on the top surface 120a of the terminal 120. In some arrangements, the catalytic layers 311 and 321 have a relatively high catalytic activity to formation of interlayers 312 and 322. In some arrangements, the catalytic layers 311 and 321 have a catalytic activity for formation of the interlayers 312 and 322 greater than that of the terminals 110 and 120. In some arrangements, a rate of formation of the interlayer 312 on the catalytic layer 311 is greater than a rate of formation of the interlayer 312 on the terminal 110. In some arrangements, a ratio of the rate of formation of the interlayer on the catalytic layer to the rate of formation of the interlayer on the terminal is greater than 1, for example, from about 10 to about 1000, or from about 50 to about 800. In some arrangements, the terminals 110 and 120 may be formed of or include Cu, and the catalytic layers 311 and 321 may be formed of or include Au, Ag, Pt, Pd, or a combination thereof. The catalytic layers 311 and 321 may be formed by coating, sputtering, electroless plating, or other suitable deposition technique.

In some arrangements, the catalytic layers 311 and 321 are formed by electroless displacement deposition (also referred to as “replacement reaction”). That is, the formation of the catalytic layers 311 and 321 consume the materials of the terminals 110 and 120; therefore, the catalytic layers 311 and 321 may be relatively thin so as to prevent overconsuming the terminals 110 and 120. In some arrangements, the catalytic layers 311 and 321 may independently have a thickness less than about 0.5 μm. In some arrangements, the catalytic layers 311 and 321 are Ag layers, and the terminals 110 and 120 are Cu pads. The plating solution for the electroless displacement deposition of the catalytic layers 311 and 321 may include AgNO₃, polyvinylpyrrolidone (PVP), citric acid, and polyethylene glycol (PEG), and the electroless displacement deposition may be represented by the following: Cu+2Ag⁺→Cu²⁺+2Ag. The above equation shows that the formation of the catalytic layers 311 and 321 (Ag layers) consume the terminals 110 and 120 (the Cu pads).

In some other arrangements, the catalytic layers 311 and 321 are formed by redox-electroless plating. That is, the redox system for the plating process is in the plating solution, and the formation of the catalytic layers 311 and 321 does not consume the materials of the terminals 110 and 120. In some arrangements, the catalytic layers 311 and 321 are Ag layers, and the terminals 110 and 120 are Cu pads. The plating solution for the redox-electroless plating of the catalytic layers 311 and 321 may include AgNO₃, NaOH, NH₃, C₆H₁₂O₆, and gelatin, and the electroless displacement deposition may be represented by the following: 2[Ag(NH₃)₃]⁺+R—COH+H₂O→2Ag+4NH₃+R—COOH+2H⁺. [Ag(NH₃)₃]⁺ may be formed from AgNO₃ and NH₃, and [Ag(NH₃)₃]⁺ may form explosive precipitates Ag₃N. With the above reaction, the thicknesses of the catalytic layers 311 and 321 may be controlled to any desired values; however, great care must be taken when the reaction is carrier out.

Referring to FIG. 4C, interlayers 312 and 322 may be formed on the catalytic layers 311 and 321, respectively, and bonding layers 313A and 323A may be formed on the interlayers 312 and 322, respectively. The interlayers 312 and 322 may be formed by coating, sputtering, electroless plating, or other suitable deposition technique. The bonding layers 313A and 323A may be formed by coating, sputtering, electroless plating, or other suitable deposition technique.

In some arrangements, the interlayers 312 and 322 are formed by redox-electroless plating. That is, the redox system for the plating process is in the plating solution, and the formation of the interlayers 312 and 322 does not consume the materials of the catalytic layers 311 and 321. Therefore, the thicknesses of the interlayers 312 and 322 may be controlled to any desired values by adjusting the plating parameters (e.g., the concentrations of components of the plating solution, the plating time, and other parameters) of the plating process. As such, the interlayers 312 and 322 having relatively large thicknesses can serve to raise the elevation of the bonding layers 313A and 323A. In some arrangements, the interlayers 312 and 322 may be formed of or include gold (Au), aluminum (Al), copper (Cu), or an alloy thereof. In some arrangements, the interlayers 312 and 322 may independently have a thickness that is equal to or greater than about 1 μm, for example, from about 1 μm to about 2 μm or from about 1 μm to about 1.5 μm.

In some arrangements, the bonding layers 313A and 323A are formed by electroless displacement deposition (or replacement reaction). That is, the formation of the bonding layers 313A and 323A consume the materials of the interlayers 312 and 322. Since the interlayers 312 and 322 may be formed with relatively large thicknesses, the consumption of the interlayers 312 and 322 during the formation of the bonding layers 313A and 323A do not substantially damage the entirety of the interlayers 312 and 322, and thus does not reduce or damage the electrical connection properties of the interlayers 312 and 322. In some arrangements, the bonding layers 313A and 323A may independently have a thickness that is equal to or greater than about 1 μm, for example, from about 1 μm to about 2 μm or from about 1 μm to about 1.5 μm.

Referring to FIG. 4D, a protective layer 40A may be formed over the bonding layers 313A and 323A. In some arrangements, the protective layer 40A entirely covers the bonding layers 313A and 323A. The protective layer 40A may be formed by coating. In some arrangements, the protective layer 40A may be formed of or include an organic dielectric material, e.g., PI.

Referring to FIG. 4E, a removal operation may be performed on the protective layer 40A. In some arrangements, the removal operation removes a portion of the protective layer 40A and portions of the bonding layers 313A and 323A to form a protective layer 40 and bonding layers 313 and 323 exposed by the protective layer 40. The removal operation may be or include a descum process, a fly cutting process, a grinding process, or the combination thereof. The removal operation may also remove portions of the bonding layers 313A and 323A. In some arrangements, the bonding layers 313 and 323 may independently have a thickness that is equal to or greater than about 0.5 μm, for example, from about 0.5 μm to about 1 μm. As such, a bonding structure 31 including the catalytic layer 311, the interlayer 312, and the bonding layer 313 may be formed, and a bonding structure 32 including the catalytic layer 321, the interlayer 322, and the bonding layer 323 may be formed.

Referring to FIG. 4F, a substrate 20 including a base layer 200, terminals 210 and 220, interconnection elements 210R and 220R, and a dielectric layer 260 may be bonded to the substrate 10 through the bonding structures 31 and 32. In some arrangements, the substrate 20 is bonded to the substrate 10 by a thermal compression bonding (TCB) process. The TCB process may be performed under a temperature from about 250° C. to about 280° C. and a pressure of about 2.5 MPa for about 30 minutes to about 2 hours. During the TCB process, the protective layer 40 may expand to fill the gap between the substrate 10 and the substrate 20 serving as a pre-bonding layer connecting the substrates 10 and 20, and the bonding layers 313 and 323 may bond to the terminals 210 and 220. As such, a bonding structure 1B is formed.

In some cases where the protective layer 40 is formed on the dielectric layer 160 with openings exposing the terminals 110 and 120, and then bonding structures (e.g., bonding layers 313 and 323) are formed in the openings of the protective layer 40. However, during the process for forming the openings, due to the required processing window to compensate the possible shifts in the positions of the openings, and also in order to provide an alignment tolerance when bonding to the terminals 210 and 220 of the substrate 20, the openings need to be made relatively large. Alternatively, the bonding layers 313 and 323 need to be made wider than the openings. As such, the sizes of the bonding layers 313 and 323 are enlarged, and thus the pitch of the terminals is enlarged, which is disadvantageous to the reduction of package size.

According to some arrangements of the present disclosure, the bonding layers 313 and 323 can be made with predetermined sizes, then the protective layer 40 is formed over the bonding layers 313 and 323, and a thinning operation is performed to expose the bonding layers 313 and 323. Therefore, the sizes of the bonding layers 313 and 323 are not increased, and thus the pitch of the terminals can be prevented from being enlarged.

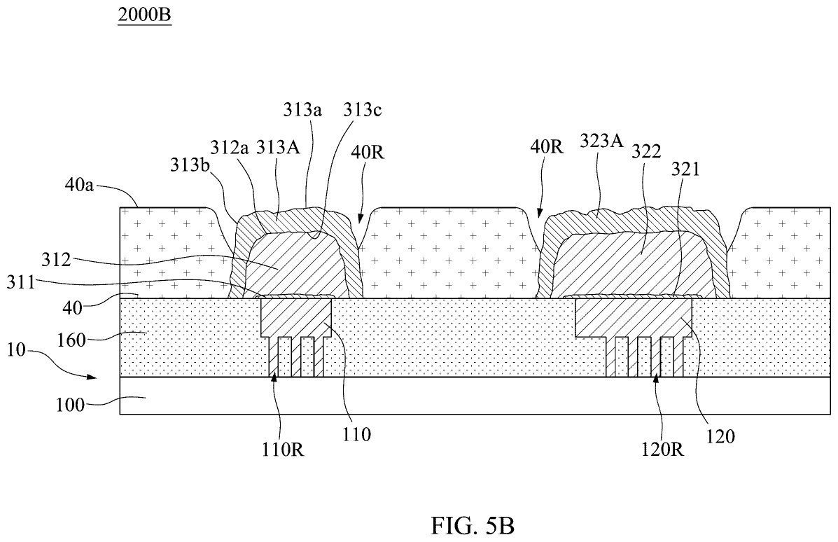

FIG. 5A illustrates one or more stages of an exemplary method for manufacturing a bonding structure in accordance with some embodiments of the present disclosure.

In some arrangements, after operations illustrated in FIGS. 4A-4D are performed, a fly cutting process may be performed on the protective layer 40A and the bonding layers 313A and 323A. The fly cutting process may be performed by guiding a cutting head (e.g., a diamond cutting head) to move along a track to scrape off portions of the protective layer 40A and the bonding layers 313A and 323A. The track may extend back and forth over the entire top surface of the protective layer 40A and the bonding layers 313A and 323A. The track may be a circular track that circles from outside toward inside to cover the entire top surface of the protective layer 40A and the bonding layers 313A and 323A. Some segments of the entire track may be adjacent to each other.

In some arrangements, the cutting head may move along one of the segments of the track to scrape off a portion the protective layer 40A and a portion of the bonding layer 313A to form a substantially flat surface 401 and an exposed substantially flat surface 313a1 of the bonding layer 313A, and then the cutting head may keep moving along another segment of the track to scrape off another portion of the protective layer 40A, another portion of the bonding layer 313A, and a portion of the bonding layer 323A to form a substantially flat surface 402, an exposed substantially flat surface 313a2 of the bonding layer 313, and an exposed substantially flat surface 323a of the bonding layer 323. Since the cutting head moving along the segments of the track may scrape off portions with different thicknesses, the surface 401 and the surface 402 may be at different elevations. In addition, the exposed top surface of the bonding layer 313 may have a stepped profile 313s formed by the surface 313a1 and the surface 313a2 at different elevations.

Next, operations illustrated in FIG. 4F may be performed to bond the substrate 20 to the substrate 10. In some arrangements, although the protective layer 40 has a non-uniform surface including the surfaces 401 and 402, after the protective layer 40 expand during the TCB process, such non-uniform surface profile would not be shown in the bonding structure 1B. Similarly, after the bonding layer 313 is bonded to the terminal 210, the non-uniform top surface profile would not be shown in the bonding structure 1B. In some arrangements, the structure illustrated in FIG. 5A may be referred to as a pre-bonding structure 2000A.

FIG. 5B illustrates one or more stages of an exemplary method for manufacturing a bonding structure in accordance with some embodiments of the present disclosure.

In some arrangements, after operations illustrated in FIGS. 4A-4D are performed, a descum process may be performed on the protective layer 40A and the bonding layers 313A and 323A. The descum process may be referred to as a plasma descum process. The protective layer 40A may be formed of or include an organic material, and the descum process may be performed by applying plasma to remove a portion of the protective layer 40A without substantially damaging the bonding layers 313A and 323A. In addition, ionized gas molecules may hit the bonding layers 313A and 323A and then bounce to the surrounding protective layer 40A, causing more of the portions of the protective layer 40A around the bonding layers 313A and 323A to be removed. As such, recesses 40R (or cavities) may be formed between the protective layer 40 and the bonding layers 313A and 323A.

Next, operations illustrated in FIG. 4F may be performed to bond the substrate 20 to the substrate 10. In some arrangements, although the protective layer 40 has recesses 40R, after the protective layer 40 expand during the TCB process, such profile would not be shown in the bonding structure 1B. Similarly, after the bonding layers 313A and 323A are bonded to the terminals 210 and 220, the non-uniform top surface profiles would not be shown in the bonding structure 1B. In some arrangements, the structure illustrated in FIG. 5B may be referred to as a pre-bonding structure 2000B.

FIG. 6A, FIG. 6B, and FIG. 6C illustrate various stages of an exemplary method for manufacturing a bonding structure 2C in accordance with some embodiments of the present disclosure.

Referring to FIG. 6A, a substrate 10 including a base layer 100, terminals 110 and 120, and a dielectric layer 160 may be provided. In some arrangements, a planarization operation (e.g., a chemical mechanical polishing operation) may be performed to expose top surfaces of the terminals 110 and 120. In some arrangements, the top surfaces of the terminals 110 and 120 are substantially aligned with or coplanar with the top surface of the dielectric layer 160.

Next, still referring to FIG. 6A, a catalytic layer 311 may be formed on the top surface of the terminal 110, and a catalytic layer 321 may be formed on the top surface of the terminal 120. The catalytic layers 311 and 321 may be formed by electroless plating. In some arrangements, the catalytic layers 311 and 321 are formed by electroless displacement deposition (or replacement reaction).

Next, still referring to FIG. 6A, interlayers 312 and 322 may be formed on the catalytic layers 311 and 321, respectively, and bonding layers 313A and 323A may be formed on the interlayers 312 and 322, respectively. The interlayers 312 and 322 may be formed by electroless plating. In some arrangements, the interlayers 312 and 322 are formed by redox-electroless plating. The bonding layers 313A and 323A may be formed by electroless plating. In some arrangements, the bonding layers 313A and 323A are formed by electroless displacement deposition (or replacement reaction). In some arrangements, the structure illustrated in FIG. 6A may be referred to as a pre-bonding structure 2000C.

Referring to FIG. 6B, a protective layer 40A may be formed over the bonding layers 313A and 323A. In some arrangements, the protective layer 40A entirely covers the bonding layers 313A and 323A. The protective layer 40A may be formed by coating. In some arrangements, the protective layer 40A may be formed of or include an organic dielectric material, e.g., PI.

Next, still referring to FIG. 6B, a removal operation may be performed on the protective layer 40A. In some arrangements, the removal operation removes a portion of the protective layer 40A and portions of the bonding layers 313A and 323A to form a protective layer 40 and the bonding layers 313A and 323A exposed by the protective layer 40. The removal operation may be or include a descum process, a fly cutting process, a grinding process, or the combination thereof. In some arrangements, the structure illustrated in FIG. 6B may be referred to as a pre-bonding structure 2000D.

Referring to FIG. 6C, a substrate 20 including a base layer 200, terminals 210 and 220, and a dielectric layer 260 may be bonded to the substrate 10. In some arrangements, the substrate 20 is bonded to the substrate 10 by a thermal compression bonding (TCB) process. The TCB process may be performed under a temperature of about 250° C. and a pressure of about 2.5 MPa for about 2 hours. During the TCB process, the protective layer 40 may expand to fill the gap between the substrate 10 and the substrate 20 serving as a pre-bonding layer connecting the substrates 10 and 20.

In some arrangements, during the TCB process, a portion of the interlayer 312 (e.g., metal molecules of the interlayer 312) may diffuse and penetrate the bonding layer 313A to form a raised portion 312A and a diffused portion 312B spaced apart from each other. In some arrangements, the diffused portion 312B contacts the terminal 210. In some arrangements, the diffused portion 312B and the terminal 210 may be formed or of include the same metal material (e.g., Cu), and no interface is formed between the diffused portion 312B and the terminal 210. In some arrangements, with the formation of the raised portion 312A and the diffused portion 312B, the metal molecules of the bonding layer 313A may diffuse toward the substrate 10 to form a bonding layer 313′. In some arrangements, the bonding layer 313′ separates the raised portion 312A from the diffused portion 312B.

In some arrangements, during the TCB process, a portion of the interlayer 322 (e.g., metal molecules of the interlayer 322) may diffuse and penetrate the bonding layer 323A to form a raised portion 322A and a diffused portion 322B spaced apart from each other. In some arrangements, the diffused portion 322B contacts the terminal 220. In some arrangements, the diffused portion 322B and the terminal 220 may be formed or of include the same metal material (e.g., Cu), and not interface is formed between the diffused portion 322B and the terminal 220. In some arrangements, with the formation of the raised portion 322A and the diffused portion 322B, the metal molecules of the bonding layer 323A may diffuse toward the substrate 10 to form a bonding layer 323′. In some arrangements, the bonding layer 323′ separates the raised portion 322A from the diffused portion 322B. As such, a bonding structure 2C is formed.

According to some arrangements of the present disclosure, no interface being formed indicates that the metal molecules of the diffused portion 312B and the terminal 210 diffuse toward each other and collectively form a monolithic structure (or integrally formed as a single piece), which is advantageous to increase the bonding strength between the bonding layer 313′ and the terminal 210.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A bonding structure, comprising:
a lower substrate;
a low melting point conductive layer disposed over the lower substrate;
a high melting point conductive layer comprising a lower portion and an upper portion, wherein the low melting point conductive layer is between the upper portion and the lower portion of the high melting point conductive layer;
a dielectric layer encapsulating the low melting point conductive layer and the high melting point conductive layer; and
an upper substrate disposed on the upper portion of high melting point conductive layer, wherein an interface between the upper substrate and the upper portion is substantially co-level with an interface between the dielectric layer and the upper substrate.

2. The bonding structure as claimed in claim 1, wherein a plurality of first grains of the upper portion of the high melting point conductive layer directly contact a pad of the upper substrate, a plurality of second grains of the pad of the upper substrate directly contact the upper portion of the high melting point conductive layer, and a quantity of the first grains is greater than a quantity of the second grains.

3. The bonding structure as claimed in claim 2, wherein a plurality of third grains of the lower portion of the high melting point conductive layer directly contact a pad of the lower substrate, a plurality of fourth grains of the pad of the lower substrate directly contact the lower portion of the high melting point conductive layer, and a quantity of the third grains is greater than a quantity of the fourth grains.

4. The bonding structure as claimed in claim 3, wherein an interface is formed between the upper portion of the high melting point conductive layer and the pad of the upper substrate.

5. The bonding structure as claimed in claim 1, wherein the low melting point conductive layer is closer to the upper substrate than to the lower substrate.

6. The bonding structure as claimed in claim 5, wherein the lower portion of the high melting point conductive layer has a curved surface, and the low melting point conductive layer is disposed along the curved surface.

7. The bonding structure as claimed in claim 6, wherein a width of the upper portion of the high melting point conductive layer is less than a width of the lower portion of the high melting point conductive layer.

8. The bonding structure as claimed in claim 6, wherein, in a cross sectional view, an interface between the upper portion of the high melting point conductive layer and the low melting point conductive layer is at least partially substantially conformal with an interface between the lower portion of the high melting point conductive layer and the low melting point conductive layer.

9. The bonding structure as claimed in claim 1, wherein a top surface of a pad of the lower substrate is substantially co-level with an interface between the dielectric layer and the lower substrate.

10. The bonding structure as claimed in claim 1, wherein the upper portion of the high melting point conductive layer tapers toward the lower substrate.

11. The bonding structure as claimed in claim 10, wherein the lower portion of the high melting point conductive layer tapers toward the upper substrate.

12. A pre-bonding structure, comprising:
a substrate;
a bonding layer disposed over the substrate; and
a pre-bonding layer encapsulating the bonding layer and exposing a top surface of the bonding layer, wherein a thickness of the pre-bonding layer is configured to prevent the substrate from being exposed by the pre-bonding layer during a thinning operation for the pre-bonding layer.

13. The pre-bonding structure as claimed in claim 12, wherein a thickness of the pre-bonding layer is greater than a thickness of a pad of the substrate.

14. The pre-bonding structure as claimed in claim 13, further comprising a raising layer on the bonding layer and collectively defining the thickness of the pre-bonding layer with the bonding layer, wherein the raised layer is configured to reduce a time of the thinning operation for the pre-bonding layer.

15. The pre-bonding structure as claimed in claim 13, wherein a range of the thickness of the pre-bonding layer is from 2 μm to 5 μm.

16. A pre-bonding structure, comprising:
a substrate comprising a first pad;
a bonding layer over the substrate and spaced apart from the first pad, wherein a melting point of the bonding layer is lower than a melting point of the first pad; and
a pre-bonding layer encapsulating the bonding layer and exposing the bonding layer, wherein a top end of a lateral surface of the bonding layer is substantially aligned with a top surface of the pre-bonding layer.

17. The pre-bonding structure as claimed in claim 16, wherein a bottom surface of the bonding layer is smoother than a top surface of the bonding layer.

18. The pre-bonding structure as claimed in claim 17, further comprising an interlayer under the bonding layer, wherein a top surface of the interlayer is closer to the top surface of the pre-bonding layer than to the first pad.

19. The pre-bonding structure as claimed in claim 18, wherein the interlayer is spaced apart from the pre-bonding layer.

20. The pre-bonding structure as claimed in claim 16, wherein the substrate further comprises a second pad, the pre-bonding structure further comprising:
a first interlayer disposed over the first pad;
a second interlayer disposed over the second pad; and
a catalytic structure disposed under the first interlayer and the second interlayer.
